(19) United States
(12) Patent Application Publication
(10) Pub. No.: US 2025/0231495 A1
(43) Pub. Date: Jul. 17, 2025

(54) METHOD AND SYSTEM FOR OBTAINING OPTICAL CRITICAL DIMENSION

(71) Applicant: TAIWAN SEMICONDUCTOR MANUFACTURING COMPANY LTD., HSINCHU (TW)

(72) Inventors: YUN-CHUNG TENG, HSINCHU CITY (TW); CHENG-HAO CHU, TAINAN CITY (TW); LI-SHIUAN TSAI, KAOHSIUNG CITY (TW); HSIEN-HUNG CHANG, HSINCHU COUNTY (TW); MIN-HSIUNG FU, HSINCHU COUNTY (TW)

(21) Appl. No.: 18/414,480

(22) Filed: Jan. 17, 2024

(51) Int. Cl. G03F 7/00

(52) U.S. Cl. CPC G03F 7/70625; G03F 7/706831; G03F 7/706837; G03F 7/706841

(57) ABSTRACT

The present disclosure provides a method and a system for obtaining OCD. The system inputs a plurality of first spectra associated with a first semiconductor structure into the first optical transformation model to output a plurality of first structure parameters; update the first structure parameters based on at least one physical parameter associated with the first semiconductor structure; establish a second optical transformation model according to the updated first structure parameters and the corresponding first spectra; and store the second optical transformation model for later OCD generation.

### BACKGROUND

Optical critical dimension (OCD) metrology is introduced to determine dimensions of a semiconductor device by measuring spectra of the semiconductor device. For example, a three-dimension model needs to be created based on some references and spectra corresponding to the references so that the three-dimension model may then be used to determine dimensions of a semiconductor device according to measured spectra of the semiconductor device. However, creating the three-dimension model is not only time-consuming but resource-intensive.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a block diagram of a system, in accordance with some embodiments of the present disclosure.

FIG. 1B is a schematic view of determining an updated optical transformation model, in accordance with some embodiments of the present disclosure.

FIG. 2A is a block diagram of a system, in accordance with some embodiments of the present disclosure.

FIG. 2B is a schematic view of establishing an initial optical transformation model, in accordance with some embodiments of the present disclosure.

FIG. 2C is a schematic view of determining an updated optical transformation model, in accordance with some embodiments of the present disclosure.

FIG. 2D is a schematic view of schematic view of generating OCD based on updated optical transformation model, in accordance with some embodiments of the present disclosure.

FIG. 3A is a block diagram of a system, in accordance with some embodiments of the present disclosure.

FIG. 3B is a schematic view of determining an updated optical transformation model, in accordance with some embodiments of the present disclosure.

FIG. 4A is a block diagram of a system, in accordance with some embodiments of the present disclosure.

FIG. 4B is a schematic view of establishing an initial optical transformation model, in accordance with some embodiments of the present disclosure.

FIG. 4C is a schematic view of determining an updated optical transformation model, in accordance with some embodiments of the present disclosure.

FIG. 4D is a schematic view of schematic view of generating OCD based on updated optical transformation model, in accordance with some embodiments of the present disclosure.

FIG. 5A is a block diagram of a system, in accordance with some embodiments of the present disclosure.

FIG. 5B is a schematic view of establishing an initial optical transformation model, in accordance with some embodiments of the present disclosure.

FIG. 5C is a schematic view of determining an updated optical transformation model, in accordance with some embodiments of the present disclosure.

FIG. 5D is a schematic view of schematic view of generating OCD based on updated optical transformation model, in accordance with some embodiments of the present disclosure.

FIG. 6 is a flowchart diagram, in accordance with some embodiments of the present disclosure.

FIG. 7 is a flowchart diagram, in accordance with some embodiments of the present disclosure.

FIG. 8 is a flowchart diagram, in accordance with some embodiments of the present disclosure.

FIG. 9 is a flowchart diagram, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

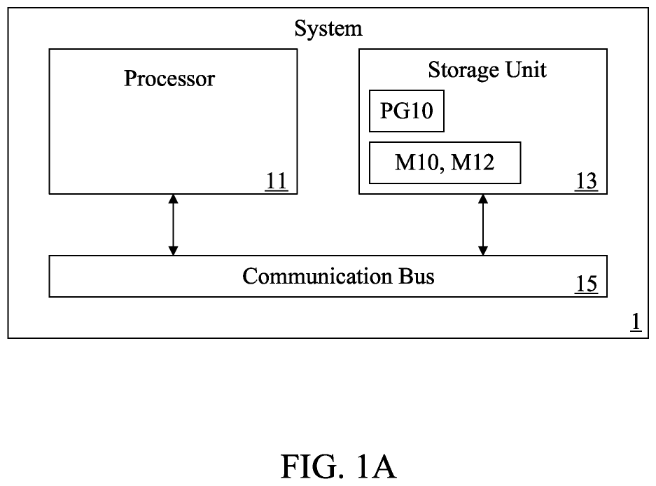

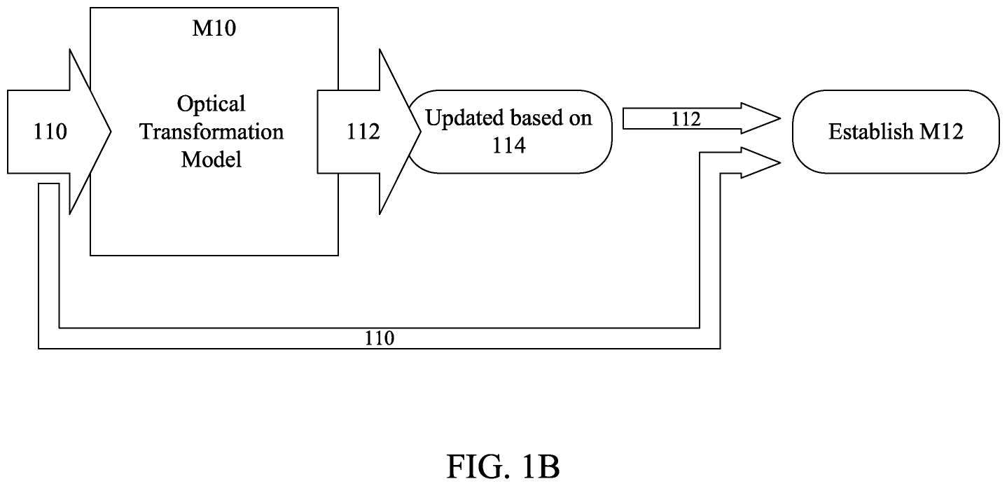

FIG. 1A illustrates a block diagram of a system 1 according to some embodiments of the present disclosure. The system 1 includes a processor 11 and a storage unit 13. The storage unit 13 stores a first optical transformation model M10 which is used for receiving measured spectrum of semiconductor device and outputting corresponding dimension. The processor 11 and the storage unit 13 are electrically coupled through a communication bus 15. The communication bus 15 may allow the processor 11 to execute a program PG10 stored in the storage unit 13. When executed, the program PG10 may generate one or more interrupts (e.g., software-interrupt) to cause the processor 11 to perform functions or instructions of the program PG10 for obtaining optical critical dimension (OCD) of semiconductor device. The functions of the program PG10 will be further described hereinafter.

FIG. 1B illustrates a schematic view of determining an updated optical transformation model according to some embodiments of the present disclosure. In some embodiments, the processor 11 is configured to input a plurality of first spectra 110 associated with a semiconductor structure into the first optical transformation model M10 to output a plurality of first structure parameters 112. The processor 11 is configured to update the first structure parameters 112 based on at least one physical parameter 114 associated with the semiconductor structure. The processor 11 is configured to establish a second optical transformation model M12 according to the updated first structure parameters 112 and the corresponding first spectra 110, and store the second optical transformation model M12 in the storage unit 13 for later use. Accordingly, the second optical transformation model M12 which is an updated optical transformation model may be used for receiving spectra associated with a semiconductor device and outputting corresponding structure parameters (e.g., dimensions) more precisely.

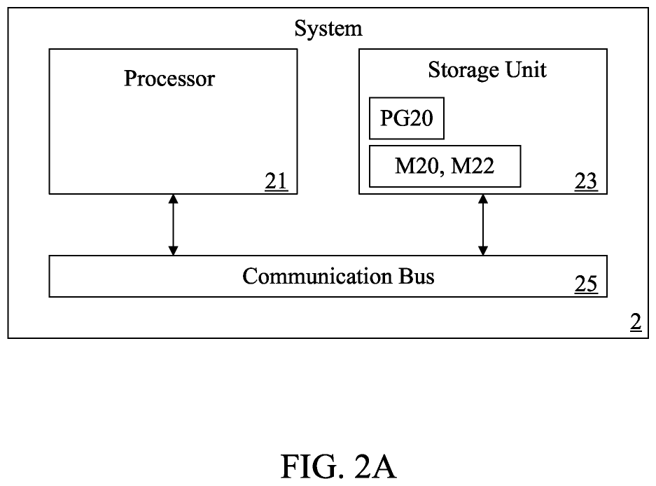

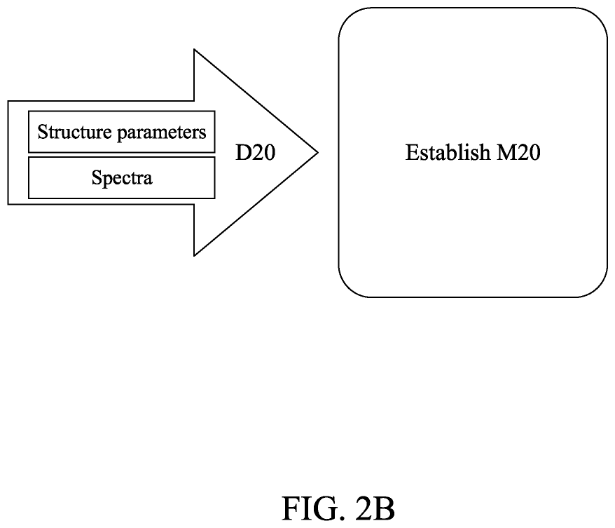

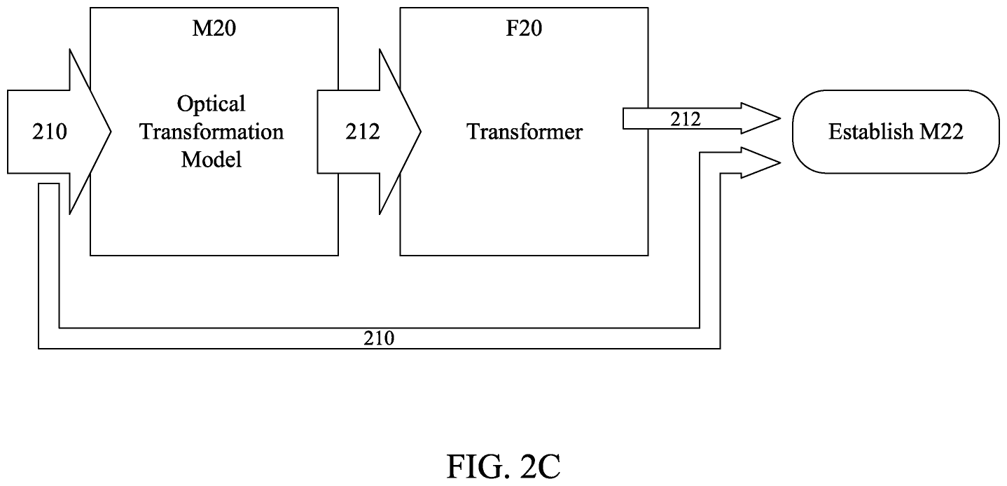

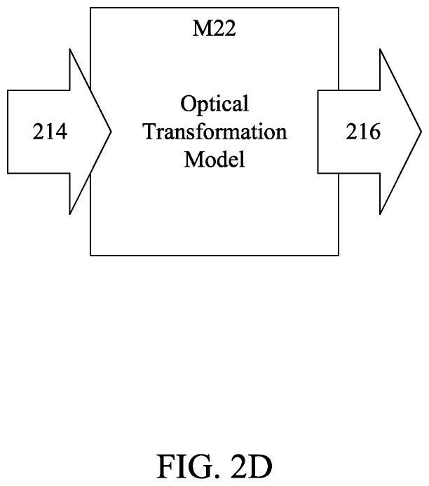

FIG. 2A illustrates a block diagram of a system 2 according to some embodiments of the present disclosure. The system 2 includes a processor 21 and a storage unit 23. The processor 21 and the storage unit 23 are electrically coupled through a communication bus 25. The communication bus 25 may allow the processor 21 to execute a program PG20 stored in the storage unit 23. When executed, the program PG20 may generate one or more interrupts (e.g., software-interrupt) to cause the processor 21 to perform functions or instructions of the program PG20 for obtaining OCD of semiconductor device. The functions of the program PG20 will be further described hereinafter.

FIG. 2B illustrates a schematic view of establishing an initial optical transformation model according to some embodiments of the present disclosure. In some embodiments, the present disclosure introduces some machine learning models for obtaining OCD of semiconductor device. In particular, the processor 21 is configured to establish a first optical transformation model M20 which is a machine learning model for converting measured spectra of semiconductor device into structure parameters. Accordingly, the first optical transformation model M20 needs to be trained by a plurality of data D20, and each data D20 is a machine learning training data which include a structure parameter and a corresponding spectrum. During the machine learning training procedure, the structure parameter is used as a training output data and the corresponding spectrum is used as a training input data. After establishment of the first optical transformation model M20 by the processor 21, the storage unit 23 stores the first optical transformation model M20. It should be noted that how to establish machine learning model (i.e., the optical transformation model of the present disclosure) with spectrum and corresponding structure parameters based on machine learning scheme shall be appreciated by those skilled in the art based on the above disclosure, and thus will not be further described herein.

FIG. 2C illustrates a schematic view of determining an updated optical transformation model according to some embodiments of the present disclosure. In some embodiments, the updated optical transformation model is generated based on some refined data, which are data outputted from the first optical transformation model M20 and then updated by some physical properties of an associated semiconductor device.

In particular, a first semiconductor structure (not shown) is measured by an optical measurement device (not shown) for obtaining a plurality of first spectra 210. The processor 21 is configured to input the plurality of first spectra 210 associated with the first semiconductor structure into the first optical transformation model M20 to output a plurality of first structure parameters 212. Then, the obtained first structure parameters 212 are updated by a transformer F20 based on at least one physical parameter associated with the first semiconductor structure. In some embodiments, the transformer F20 is a pre-determined function for receiving the first structure parameters 212 and outputted the updated first structure parameters 212.

Then, the processor 21 is configured to establish a second optical transformation model M22 which is a machine learning model for converting measured spectra of semiconductor device into structure parameters. The second optical transformation model M22 are trained by a plurality of data, and each data is a machine learning training data which include one updated first structure parameter 212 and one corresponding spectrum 210. During the machine learning training procedure, the updated first structure parameter 212 is used as a training output data and the corresponding spectrum 210 is used as a training input data. After establishment of the second optical transformation model M22 by the processor 21, the storage unit 23 stores the second optical transformation model M22.

In some embodiments, the second optical transformation model M22 is the updated optical transformation model based on the first optical transformation model M20 based on some refined data (i.e., the updated first structure parameters 212), and is capable of generating structure parameters more precise than the first optical transformation model M20 is capable of.

FIG. 2D illustrates a schematic view of generating OCD based on updated optical transformation model according to some embodiments of the present disclosure. For the upcoming OCD generations, the second optical transformation model M22 is used. In particular, the processor 21 is configured to input a plurality of second spectra 214 associated with a second semiconductor structure into the second optical transformation model M22 to output a plurality of second structure parameters 216 which are more precise machine learning outputs.

In some embodiments, the structure parameter (e.g., the first structure parameter 212 or the second structure parameter 216) includes a dimension of the associated semiconductor device (e.g., the first semiconductor device or the second semiconductor device). For example, the dimension is width, height, thickness or angle of the associated semiconductor device.

In some embodiments, the at least one physical parameter associated with the first semiconductor structure includes a wafer radius, a wavelength or a process recipe associated with the first semiconductor structure, and the transformer F20 receives the first structure parameters 212 and outputted the updated first structure parameters 212 based on the at least one physical parameter. For example, when the physical parameter is a wafer radius of a wafer where the first semiconductor structure is in, whether the location of the first semiconductor structure is near the center of the wafer affects a width (i.e., the first structure parameters 212) of an opening of the first semiconductor structure. Therefore, the transformer F20 is pre-determined for adjusting the width of the opening of the first semiconductor structure based on the distance between the location of the first semiconductor structure on the wafer and the center of the wafer.

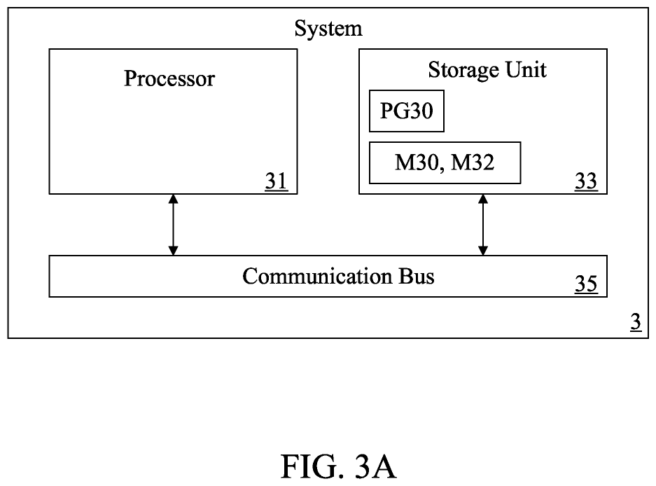

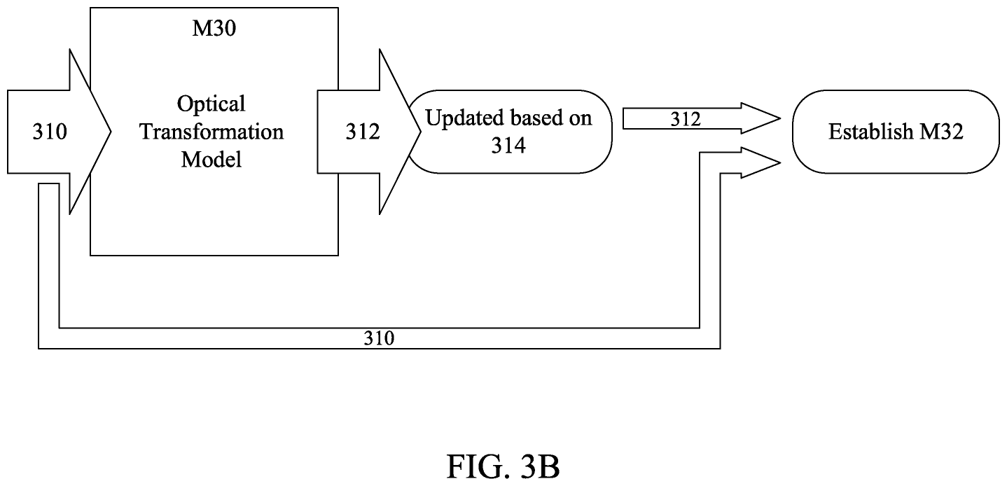

FIG. 3A illustrates a block diagram of a system 3 according to some embodiments of the present disclosure. The system 3 includes a processor 31 and a storage unit 33. The storage unit 33 stores a first optical transformation model M30 which is used for receiving measured spectrum of semiconductor device and outputting corresponding dimensions. The processor 31 and the storage unit 33 are electrically coupled through a communication bus 35. The communication bus 35 may allow the processor 31 to execute a program PG30 stored in the storage unit 33. When executed, the program PG30 may generate one or more interrupts (e.g., software-interrupt) to cause the processor 31 to perform functions or instructions of the program PG30 for obtaining OCD of semiconductor device. The functions of the program PG30 will be further described hereinafter.

FIG. 3B illustrates a schematic view of determining an updated optical transformation model according to some embodiments of the present disclosure. In some embodiments, the processor 31 is configured to input a plurality of first spectra 310 associated with a semiconductor structure into the first optical transformation model M30 to output a plurality of first structure parameter sets 312. Each first structure parameter set 312 includes a structure parameter associated with the semiconductor structure and a structure parameter associated with a previous structure of the semiconductor structure. The processor 31 is configured to update the structure parameters of the first structure parameter sets 312 based on at least one physical parameter 314 associated with the semiconductor structure. The processor 31 is configured to establish a second optical transformation model M32 according to the updated first structure parameter sets 312 and the corresponding first spectra 310, and store the second optical transformation model M32 in the storage unit 33 for later use. Accordingly, the second optical transformation model M32 which is an updated optical transformation model may be used for receiving spectra associated with a semiconductor device and outputting corresponding structure parameters (e.g., dimensions) more precisely.

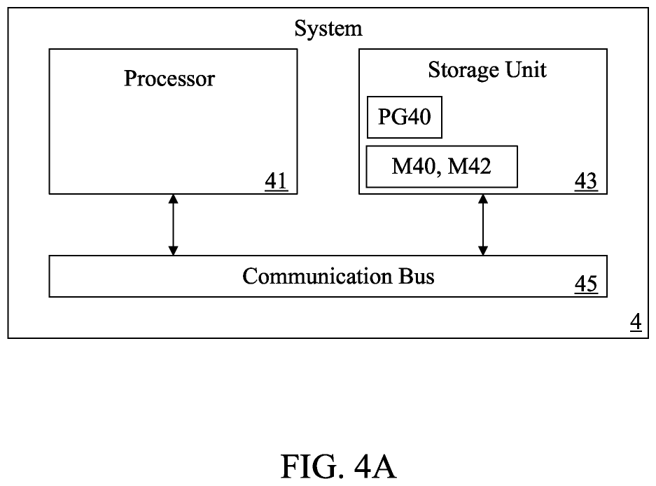

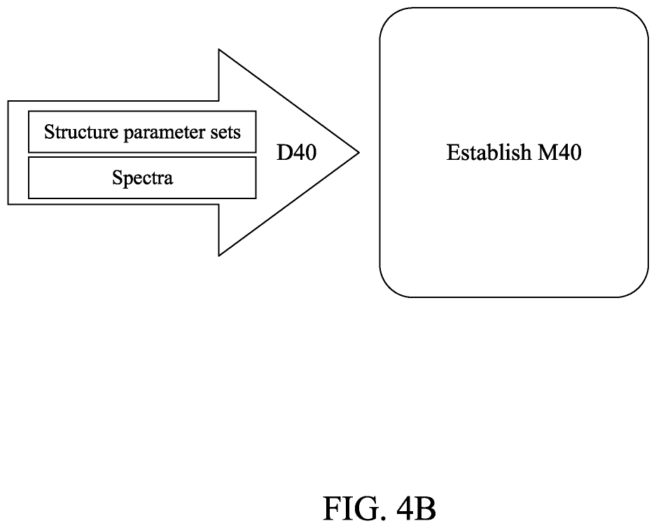

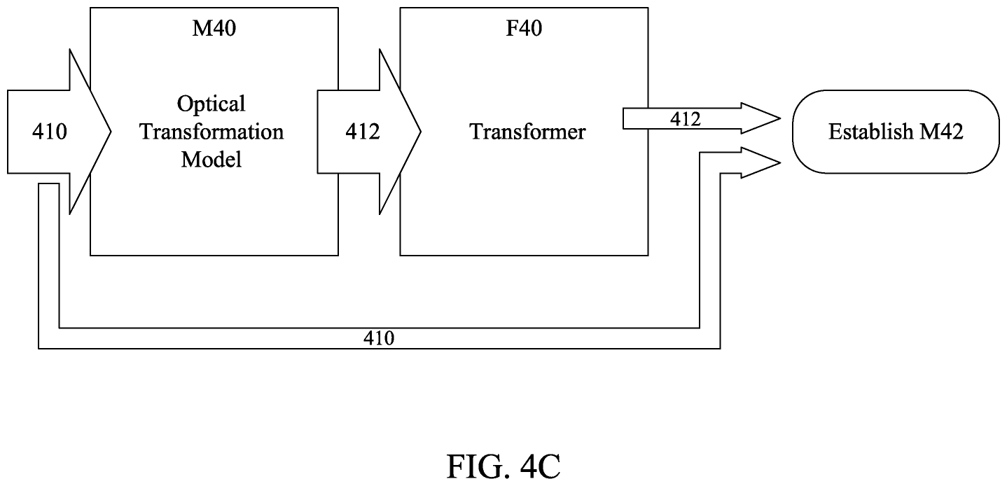

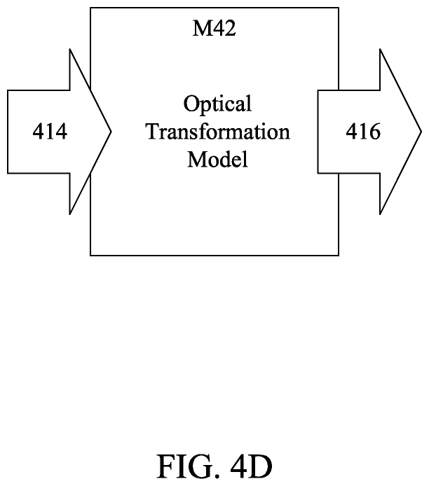

FIG. 4A illustrates a block diagram of a system 4 according to some embodiments of the present disclosure. The system 4 includes a processor 41 and a storage unit 43. The processor 41 and the storage unit 43 are electrically coupled through a communication bus 45. The communication bus 45 may allow the processor 41 to execute a program PG40 stored in the storage unit 43. When executed, the program PG40 may generate one or more interrupts (e.g., software-interrupt) to cause the processor 41 to perform functions or instructions of the program PG40 for obtaining OCD of semiconductor device. The functions of the program PG40 will be further described hereinafter.

FIG. 4B illustrates a schematic view of establishing an initial optical transformation model according to some embodiments of the present disclosure. In some embodiments, the present disclosure introduces some machine learning models for obtaining OCD of semiconductor device. In some embodiments, because a previous structure of a semiconductor structure may affect a spectrum of a present structure of the semiconductor structure, a structure parameter of the previous structure of the semiconductor structure and a structure parameter of the present structure of the semiconductor structure may be introduced for establishing the machine learning models.

In particular, the processor 41 is configured to establish a first optical transformation model M40 which is a machine learning model for converting measured spectra of semiconductor device into structure parameter sets. Each structure parameter set includes a structure parameter associated with a present structure of a first semiconductor structure and a structure parameter associated with a previous structure of the first semiconductor structure. For example, each structure parameter set includes a first structure parameter and a second structure parameter. The first structure parameter is associated with the first semiconductor structure after a specific process, and the second structure parameter is associated with the first semiconductor structure before the specific process.

Accordingly, the first optical transformation model M40 needs to be trained by a plurality of data D40, and each data D40 is a machine learning training data which include a structure parameter set and a corresponding spectrum. During the machine learning training procedure, the structure parameter set is used as a training output data and the corresponding spectrum is used as a training input data. After establishment of the first optical transformation model M40 by the processor 41, the storage unit 43 stores the first optical transformation model M40. It should be noted that how to establish machine learning model (i.e., the optical transformation model of the present disclosure) with spectrum and corresponding structure parameter sets based on machine learning scheme shall be appreciated by those skilled in the art based on the above disclosure, and thus will not be further described herein.

FIG. 4C illustrates a schematic view of determining an updated optical transformation model according to some embodiments of the present disclosure. In some embodiments, the updated optical transformation model is generated based on some refined data, which are data outputted from the first optical transformation model M40 and then updated by some physical properties of an associated semiconductor device.

In particular, a first semiconductor structure (not shown) is measured by an optical measurement device (not shown) for obtaining a plurality of first spectra 410. The processor 41 is configured to input the plurality of first spectra 410 associated with the first semiconductor structure into the first optical transformation model M40 to output a plurality of first structure parameter sets 412. Then, the obtained first structure parameter sets 412 are updated by a transformer F40 based on at least one physical parameter associated with the first semiconductor structure. In some embodiments, the transformer F40 is a pre-determined function for receiving the first structure parameter sets 412 and outputted the updated first structure parameter sets 412.

Then, the processor 41 is configured to establish a second optical transformation model M42 which is a machine learning model for converting spectra into structure parameters. The second optical transformation model M42 are trained by a plurality of data, and each data is a machine learning training data which include one updated first structure parameter set 412 and one corresponding spectrum 410. During the machine learning training procedure, the updated first structure parameter set 412 is used as a training output data and the corresponding spectrum 410 is used as a training input data. After establishment of the second optical transformation model M42 by the processor 41, the storage unit 43 stores the second optical transformation model M42.

In some embodiments, the second optical transformation model M42 is the updated optical transformation model based on the first optical transformation model M40 with some refined data (i.e., the updated first structure parameter sets 412), and is capable of generating structure parameters more precise than the first optical transformation model M40 is capable of.

FIG. 4D illustrates a schematic view of generating OCD based on updated optical transformation model according to some embodiments of the present disclosure. For the upcoming OCD generations, the second optical transformation model M42 is used. In particular, the processor 41 is configured to input a plurality of second spectra 414 associated with a second semiconductor structure into the second optical transformation model M42 to output a plurality of second structure parameter sets 416 which are more precise machine learning outputs. More specifically, one second structure parameter set 416 includes a structure parameter associated with a present structure of the second semiconductor structure and a structure parameter associated with a previous structure of the second semiconductor structure. Because an additional factor of the previous structure of the second semiconductor structure is introduced and considered during the machine learning procedure, the structure parameter associated with the present structure of the second semiconductor structure may be more precise.

In some embodiments, the structure parameters of the structure parameter sets (e.g., the first structure parameter set 412 or the second structure parameter set 416) includes a dimension of the associated semiconductor device (e.g., the first semiconductor device or the second semiconductor device). For example, the dimension is width, height, thickness or angle of the associated semiconductor device.

In some embodiments, the at least one physical parameter associated with the first semiconductor structure includes a wafer radius, a wavelength or a process recipe associated with the first semiconductor structure, and the transformer F40 receives the first structure parameter sets 412 and outputted the updated first structure parameter sets 412 based on the at least one physical parameter. For example, when the physical parameter is a process recipe of processing a wafer where the first semiconductor structure is in, the process recipe may affect angles (i.e., the structure parameter, which is associated with the present structure, of the first structure parameter set 412) of elements of the first semiconductor structure. Therefore, the transformer F40 is pre-determined for adjusting the angles of the elements of the first semiconductor structure based on the process recipe.

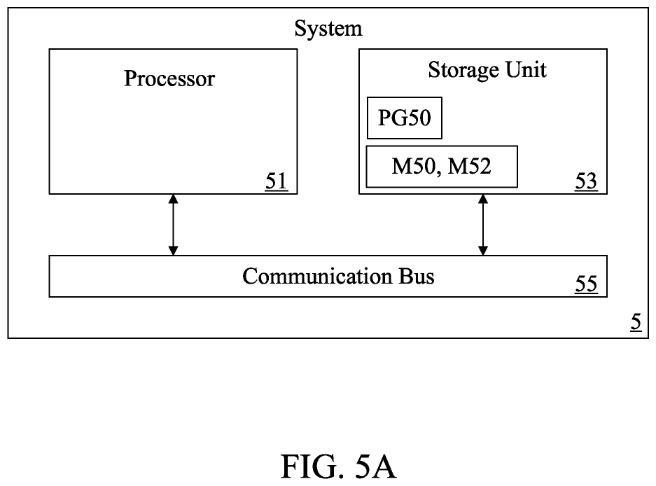

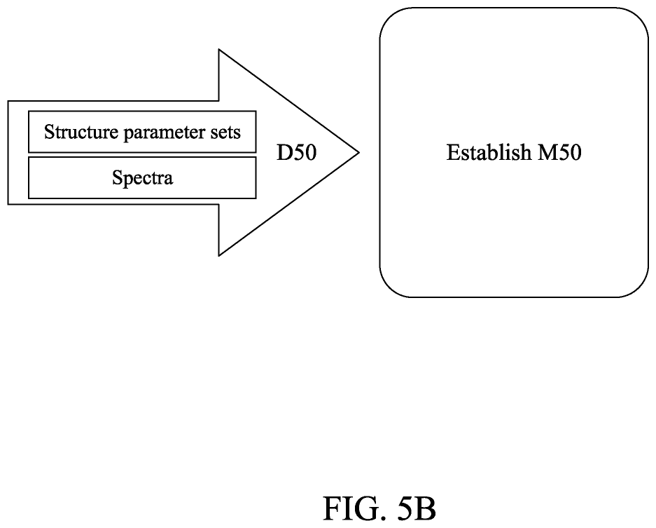

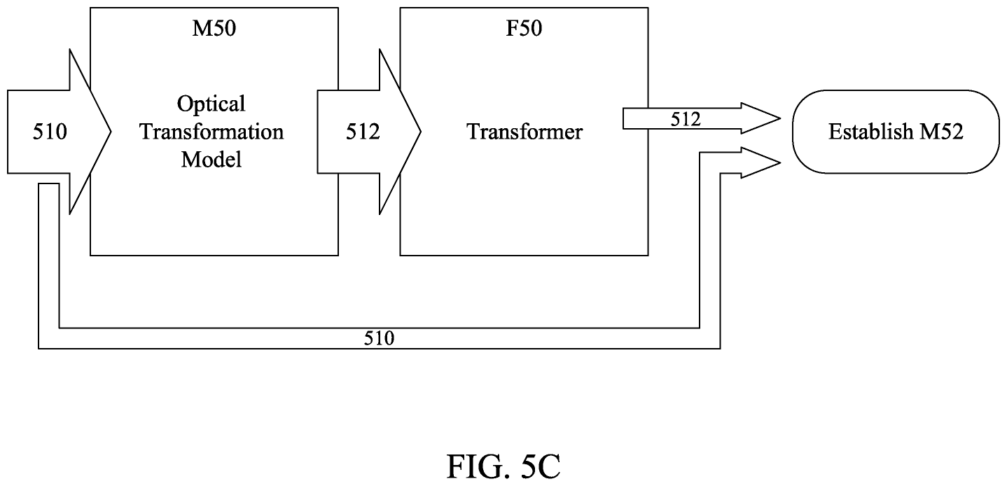

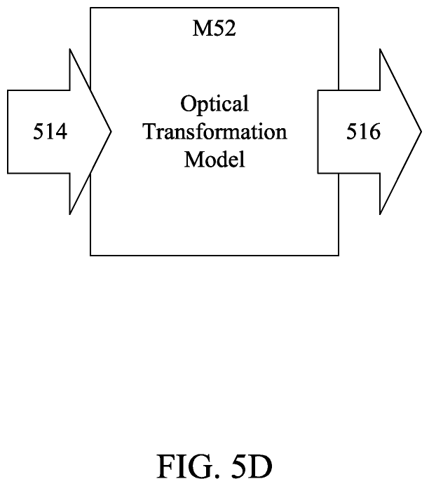

FIG. 5A illustrates a block diagram of a system 5 according to some embodiments of the present disclosure. The system 5 includes a processor 51 and a storage unit 53. The processor 51 and the storage unit 53 are electrically coupled through a communication bus 55. The communication bus 55 may allow the processor 51 to execute a program PG50 stored in the storage unit 53. When executed, the program PG50 may generate one or more interrupts (e.g., software-interrupt) to cause the processor 51 to perform functions or instructions of the program PG50 for obtaining OCD of semiconductor device. The functions of the program PG50 will be further described hereinafter.

FIG. 5B illustrates a schematic view of establishing an initial optical transformation model according to some embodiments of the present disclosure. In some embodiments, the present disclosure introduces some machine learning models for obtaining OCD of semiconductor device. In some embodiments, because previous structures of a semiconductor structure may affect a spectrum of a present structure of the semiconductor structure, structure parameters of the previous structures of the semiconductor structure and a structure parameter of the present structure of the semiconductor structure may be introduced for establishing the machine learning models.

In particular, the processor 51 is configured to establish a first optical transformation model M50 which is a machine learning model for converting measured spectra of semiconductor device into structure parameter sets. Each structure parameter set includes a structure parameter associated with a present structure of a first semiconductor structure and structure parameters associated with previous structures of the first semiconductor structure. For example, each structure parameter set includes: (1) a first structure parameter; (2) a second structure parameter; and (3) a third structure parameter. The first structure parameter is associated with the first semiconductor structure after a first process, the second structure parameter is associated with the first semiconductor structure between the first process and a second process, and the third structure parameter is associated with the first semiconductor structure before the second process.

Accordingly, the first optical transformation model M50 needs to be trained by a plurality of data D50, and each data D50 is a machine learning training data which include a structure parameter set and a corresponding spectrum. During the machine learning training procedure, the structure parameter set is used as a training output data and the corresponding spectrum is used as a training input data. After establishment of the first optical transformation model M50 by the processor 51, the storage unit 53 stores the first optical transformation model M50.

FIG. 5C illustrates a schematic view of determining an updated optical transformation model according to some embodiments of the present disclosure. In some embodiments, the updated optical transformation model is generated based on some refined data, which are data outputted from the first optical transformation model M50 and then updated by some physical properties of an associated semiconductor device.

In particular, a first semiconductor structure (not shown) is measured by an optical measurement device (not shown) for obtaining a plurality of first spectra 510. The processor 51 is configured to input the plurality of first spectra 510 associated with the first semiconductor structure into the first optical transformation model M50 to output a plurality of first structure parameter sets 512. Then, the obtained first structure parameter sets 512 are updated by a transformer F50 based on at least one physical parameter associated with the first semiconductor structure. In some embodiments, the transformer F50 is a pre-determined function for receiving the first structure parameter sets 512 and outputted the updated first structure parameter sets 512.

Then, the processor 51 is configured to establish a second optical transformation model M52 which is a machine learning model for converting spectra into structure parameters. The second optical transformation model M52 are trained by a plurality of data, and each data is a machine learning training data which include one updated first structure parameter set 512 and one corresponding spectrum 510. During the machine learning training procedure, the updated first structure parameter set 512 is used as a training output data and the corresponding spectrum 510 is used as a training input data. After establishment of the second optical transformation model M52 by the processor 51, the storage unit 53 stores the second optical transformation model M52.

In some embodiments, the second optical transformation model M52 is the updated optical transformation model based on the first optical transformation model M50 with some refined data (i.e., the updated first structure parameter sets 512), and is capable of generating structure parameters more precise than the first optical transformation model M50 is capable of.

FIG. 5D illustrates a schematic view of generating OCD based on updated optical transformation model according to some embodiments of the present disclosure. For the upcoming OCD generations, the second optical transformation model M52 is used. In particular, the processor 51 is configured to input a plurality of second spectra 514 associated with a second semiconductor structure into the second optical transformation model M52 to output a plurality of second structure parameter sets 516 which are more precise machine learning outputs. More specifically, one second structure parameter set 516 includes a structure parameter associated with a present structure of the second semiconductor structure and structure parameters associated with previous structures of the second semiconductor structure. Because additional factors of the previous structures of the second semiconductor structure are introduced and considered during the machine learning procedure, the structure parameter associated with the present structure of the second semiconductor structure may be more precise.

In some embodiments, the structure parameters of the structure parameter sets (e.g., the first structure parameter set 512 or the second structure parameter set 516) includes a dimension of the associated semiconductor device (e.g., the first semiconductor device or the second semiconductor device). For example, the dimension is width, height, thickness or angle of the associated semiconductor device.

In some embodiments, the at least one physical parameter associated with the first semiconductor structure includes a wafer radius, a wavelength or a process recipe associated with the first semiconductor structure, and the transformer F50 receives the first structure parameter sets 512 and outputted the updated first structure parameter sets 512 based on the at least one physical parameter. For example, when the physical parameter is a wafer radius of a wafer where the first semiconductor structure is in, whether the location of the first semiconductor structure is near the center of the wafer affects a width (i.e., the structure parameter, which is associated with the present structure, of the first structure parameter set 512) of an opening of the first semiconductor structure. Therefore, the transformer F50 is pre-determined for adjusting the width of the opening of the first semiconductor structure based on the distance between the location of the first semiconductor structure on the wafer and the center of the wafer.

In some embodiments, the first optical transformation model may be utilized for establishing the second optical transformation model during the operations of the present disclosure. In some embodiments, the second optical transformation model may be utilized for establishing a third optical transformation model and so forth.

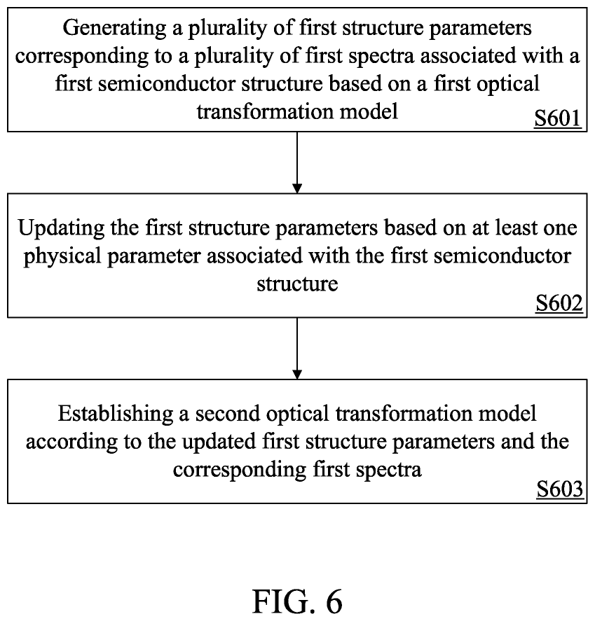

Some embodiments of the present disclosure include a method for generating an optical transformation model which is used for obtaining OCD of semiconductor device, and a flowchart diagram thereof is as shown in FIG. 6. The method of some embodiments is implemented by a system (e.g., the system 1) of the aforesaid embodiments. Detailed operations of the method are as follows.

Referring to FIG. 6, operation S601 is executed to generate a plurality of first structure parameters corresponding to a plurality of first spectra associated with a first semiconductor structure based on a first optical transformation model. Operation S602 is executed to update the first structure parameters based on at least one physical parameter associated with the first semiconductor structure. Operation S603 is executed to establish a second optical transformation model according to the updated first structure parameters and the corresponding first spectra.

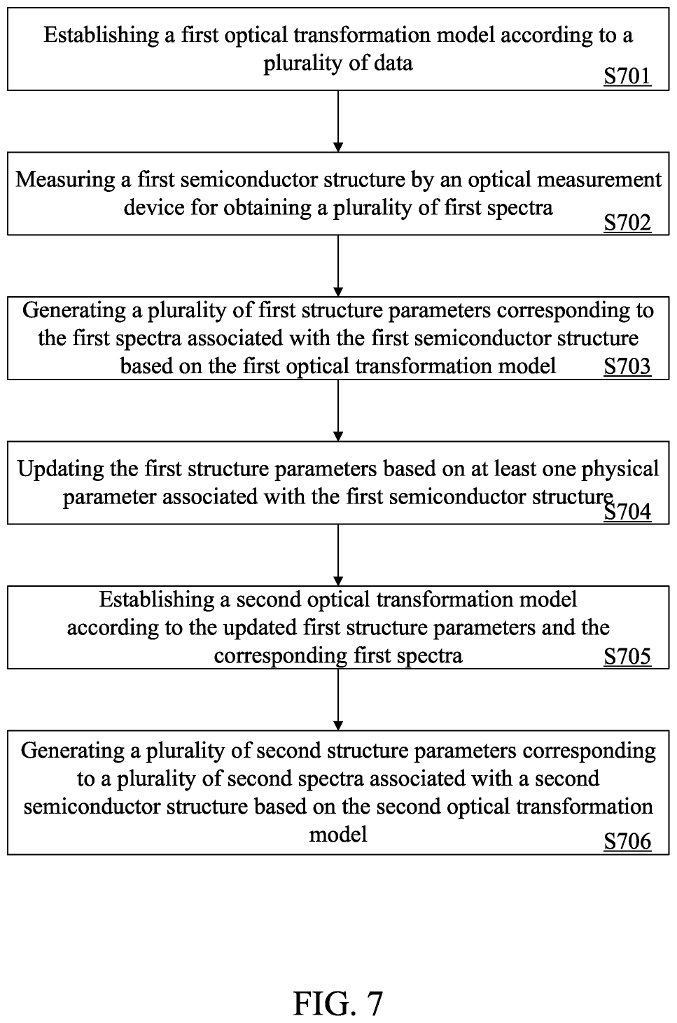

Some embodiments of the present disclosure include a method for generating an optical transformation model which is used for obtaining OCD of semiconductor device, and a flowchart diagram thereof is as shown in FIG. 7. The method of some embodiments is implemented by a system (e.g., the system 2) of the aforesaid embodiments. Detailed operations of the method are as follows.

Referring to FIG. 7, operation S701 is executed to establish a first optical transformation model according to a plurality of data. Each data includes a structure parameter and a corresponding spectrum. Operation S702 is executed to measure a first semiconductor structure by an optical measurement device for obtaining a plurality of first spectra. Operation S703 is executed to generate a plurality of first structure parameters corresponding to the first spectra associated with the first semiconductor structure based on the first optical transformation model. Operation S704 is executed to update the first structure parameters by a transformer based on the at least one physical parameter associated with the first semiconductor structure. Operation S705 is executed to establish a second optical transformation model according to the updated first structure parameters and the corresponding first spectra. Operation S706 is executed to generate a plurality of second structure parameters corresponding to a plurality of second spectra associated with a second semiconductor structure based on the second optical transformation model.

In some embodiments, the first optical transformation model and the second optical transformation model are established based on a machine learning scheme. The structure parameter includes a dimension (e.g., such as width, height, thickness or angle). The transformer is a pre-determined function for receiving the first structure parameters and outputted the updated first structure parameters, and the at least one physical parameter includes a wafer radius, a wavelength or a process recipe.

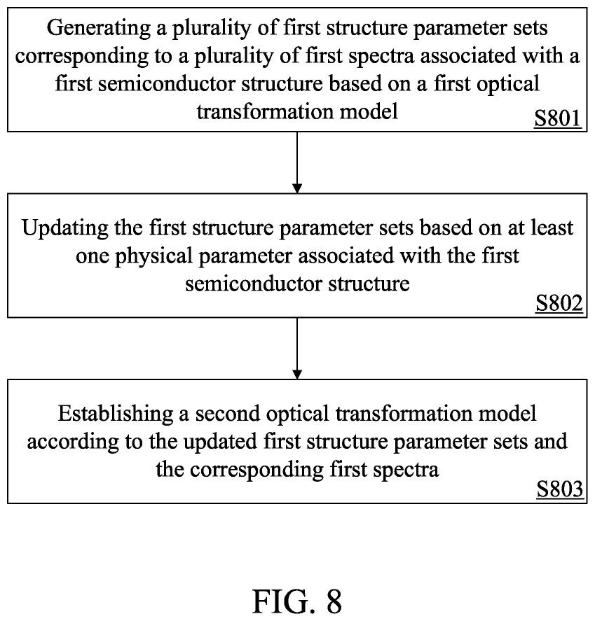

Some embodiments of the present disclosure include a method for generating an optical transformation model which is used for obtaining OCD of semiconductor device, and a flowchart diagram thereof is as shown in FIG. 8. The method of some embodiments is implemented by a system (e.g., the system 3) of the aforesaid embodiments. Detailed operations of the method are as follows.

Referring to FIG. 8, operation S801 is executed to generate a plurality of first structure parameter sets corresponding to a plurality of first spectra associated with a first semiconductor structure based on a first optical transformation model. Operation S802 is executed to update the first structure parameter sets based on at least one physical parameter associated with the first semiconductor structure. Operation S803 is executed to establish a second optical transformation model according to the updated first structure parameters and the corresponding first spectra.

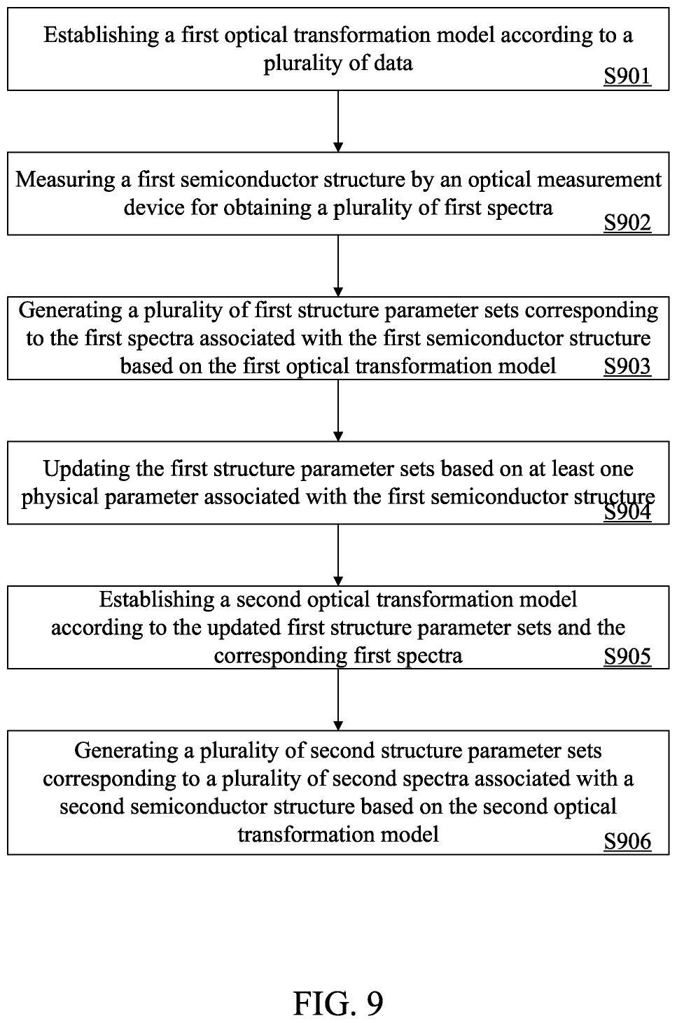

Some embodiments of the present disclosure include a method for generating an optical transformation model which is used for obtaining OCD of semiconductor device, and a flowchart diagram thereof is as shown in FIG. 9. The method of some embodiments is implemented by a system (e.g., the system 4) of the aforesaid embodiments. Detailed operations of the method are as follows.

Referring to FIG. 9, operation S901 is executed to establish a first optical transformation model according to a plurality of data. Each data includes a structure parameter set and a corresponding spectrum, and the structure parameter set includes a structure parameter associated with a specific semiconductor structure and one or more structure parameters associated with one or more previous structures of the specific semiconductor structure. Operation S902 is executed to measure a first semiconductor structure by an optical measurement device for obtaining a plurality of first spectra. Operation S903 is executed to generate a plurality of first structure parameter sets corresponding to the first spectra associated with the first semiconductor structure based on the first optical transformation model. Each first structure parameter set includes a structure parameter associated with the first semiconductor structure and one or more structure parameters associated with one or more previous structures of the first semiconductor structure. Operation S904 is executed to update the first structure parameter sets by a transformer based on the at least one physical parameter associated with the first semiconductor structure. Operation S905 is executed to establish a second optical transformation model according to the updated first structure parameter sets and the corresponding first spectra. Operation S906 is executed to generate a plurality of second structure parameter sets corresponding to a plurality of second spectra associated with a second semiconductor structure based on the second optical transformation model. Each second structure parameter set include a structure parameter associated with the second semiconductor structure and one or more structure parameters associated with one or more previous structures of the second semiconductor structure.

In some embodiments, the first optical transformation model and the second optical transformation model are established based on a machine learning scheme. Each structure parameter of the structure parameter set includes a dimension (e.g., such as width, height, thickness or angle). The transformer is a pre-determined function for receiving the first structure parameter sets and outputted the updated first structure parameter sets, and the at least one physical parameter includes a wafer radius, a wavelength or a process recipe.

The method described in each of the above embodiments may be implemented by a computer program including a plurality of codes. The computer program is stored in a non-transitory computer readable storage medium. When the computer programs loaded into an electronic computing apparatus (e.g., the defect determination system mentioned in the above embodiments), the computer program executes the defect determination method as described in the above embodiment. The non-transitory computer readable storage medium may be an electronic product, e.g., a read only memory (ROM), a flash memory, a floppy disk, a hard disk, a compact disk (CD), a mobile disk, a database accessible to networks, or any other storage media with the same function and well known to those of ordinary skill in the art.

Some embodiments of the present disclosure provide a method for obtaining OCD. The method includes the operations of: generating a plurality of first structure parameters corresponding to a plurality of first spectra associated with a first semiconductor structure based on a first optical transformation model; updating the first structure parameters based on at least one physical parameter associated with the first semiconductor structure; and establishing a second optical transformation model according to the updated first structure parameters and the corresponding first spectra.

Some embodiments of the present disclosure provide a method for obtaining OCD. The method includes the operations of: generating a plurality of first structure parameter sets corresponding to a plurality of first spectra associated with a first semiconductor structure based on a first optical transformation model, wherein each first structure parameter set includes a structure parameter associated with the first semiconductor structure and a structure parameter associated with a previous structure of the first semiconductor structure; updating the first structure parameter sets based on at least one physical parameter associated with the first semiconductor structure; and establishing a second optical transformation model according to the updated first structure parameter sets and the corresponding first spectra.

Some embodiments of the present disclosure provide a system for obtaining OCD. The system includes a storage unit and a processor. The processor is connected to the storage unit electrically. The storage unit stores a first optical transformation model. The processor: input a plurality of first spectra associated with a first semiconductor structure into the first optical transformation model to output a plurality of first structure parameters; update the first structure parameters based on at least one physical parameter associated with the first semiconductor structure; establish a second optical transformation model according to the updated first structure parameters and the corresponding first spectra; and store the second optical transformation model in the storage unit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
generating a plurality of first structure parameters corresponding to a plurality of first spectra associated with a first semiconductor structure based on a first optical transformation model;
updating the first structure parameters based on at least one physical parameter associated with the first semiconductor structure; and
establishing a second optical transformation model according to the updated first structure parameters and the corresponding first spectra.

2. The method of claim 1, further comprising:
establishing the first optical transformation model according to a plurality of data, wherein each data includes a structure parameter and a corresponding spectrum.

3. The method of claim 2, wherein the first optical transformation model and the second optical transformation model are established based on a machine learning scheme.

4. The method of claim 1, wherein the step of updating the first structure parameters based on the at least one physical parameter associated with the first semiconductor structure further comprises:
updating the first structure parameters by a transformer based on the at least one physical parameter associated with the first semiconductor structure.

5. The method of claim 1, further comprising:
generating a plurality of second structure parameters corresponding to a plurality of second spectra associated with a second semiconductor structure based on the second optical transformation model.

6. The method of claim 1, wherein each first structure parameter includes a dimension.

7. The method of claim 1, wherein the at least one physical parameter includes a wafer radius, a wavelength or a process recipe.

8. The method of claim 1, further comprising:
measuring the first semiconductor structure by an optical measurement device for obtaining the first spectra.

9. A method, comprising:
generating a plurality of first structure parameter sets corresponding to a plurality of first spectra associated with a first semiconductor structure based on a first optical transformation model, wherein each first structure parameter set includes a structure parameter associated with the first semiconductor structure and a structure parameter associated with a previous structure of the first semiconductor structure;
updating the first structure parameter sets based on at least one physical parameter associated with the first semiconductor structure; and
establishing a second optical transformation model according to the updated first structure parameter sets and the corresponding first spectra.

10. The method of claim 9, further comprising:
establishing the first optical transformation model according to a plurality of data, wherein each data includes a structure parameter set and a corresponding spectrum.

11. The method of claim 10, wherein the first optical transformation model and the second optical transformation model are established based on a machine learning scheme.

12. The method of claim 9, wherein the step of updating the first structure parameter sets based on at least one physical parameter associated with the first semiconductor structure further comprises:
updating the first structure parameter sets by a transformer based on the at least one physical parameter associated with the first semiconductor structure.

13. The method of claim 9, further comprising:
generating a plurality of second structure parameter sets corresponding to a plurality of second spectra associated with a second semiconductor structure based on the second optical transformation model.

14. The method of claim 9, wherein in each first structure parameter set, the structure parameter associated with the first semiconductor structure includes a dimension, and the structure parameter associated with the previous structure of the first semiconductor structure includes a dimension.

15. The method of claim 9, wherein the at least one physical parameter includes a wafer radius, a wavelength or a process recipe.

16. The method of claim 9, wherein each first structure parameter set further includes a structure parameter associated with another previous structure of the first semiconductor structure.

17. A system, comprising:
a storage unit, being configured to store a first optical transformation model;
a processor, being connected to the storage unit electrically and configured to:
input a plurality of first spectra associated with a first semiconductor structure into the first optical transformation model to output a plurality of first structure parameters;
update the first structure parameters based on at least one physical parameter associated with the first semiconductor structure;
establish a second optical transformation model according to the updated first structure parameters and the corresponding first spectra; and
store the second optical transformation model in the storage unit.

18. The system of claim 17, wherein the processor is further configured to:
establish the first optical transformation model according to a plurality of data, wherein each data includes a structure parameter and a corresponding spectrum.

19. The system of claim 17, wherein the processor is further configured to:
input the first structure parameters into a transformer to update the first structure parameters.

20. The system of claim 17, wherein the processor is further configured to:
input a plurality of second spectra associated with a second semiconductor structure into the second optical transformation model to output a plurality of second structure parameters.
